(19) United States
(12) Patent Application Publication
(10) Pub. No.: US 2024/0155946 A1
(43) Pub. Date: May 9, 2024

(54) THERMOELECTRIC ARRAY DISPLAY AND MANUFACTURING METHOD THEREOF

(71) Applicant: WUHAN UNIVERSITY, Wuhan (CN)

(72) Inventors: Ziyu WANG, Wuhan (CN); Xingzhong ZHANG, Wuhan (CN); Yong LIU, Wuhan (CN); Wei WU, Wuhan (CN); Xiaosa LIANG, Wuhan (CN); Rui XIONG, Wuhan (CN)

(73) Assignee: WUHAN UNIVERSITY, Wuhan (CN)

(21) Appl. No.: 18/281,962

(22) PCT Filed: Nov. 16, 2022
(86) PCT No.: PCT/CN2022/132212

§ 371 Date: Sep. 14, 2023

(30) Foreign Application Priority Data
Dec. 9, 2021 (CN) 202111498529.7
Dec. 9, 2021 (CN) 202111517702.3

(51) Int. Cl. H10N 10/17; H10N 10/01; H10N 10/817; H10N 10/851; H10N 10/852

(52) U.S. Cl. CPC H10N 10/17; H10N 10/01; H10N 10/817; H10N 10/852; H10N 10/8556

(57) ABSTRACT

A thermoelectric array display and a manufacturing method thereof are provided. The thermoelectric array display includes at least a first pixel, where the first pixel includes a bottom electrode, a P-type thermoelectric leg, an N-type thermoelectric leg, and a top electrode; the P-type thermoelectric leg is arranged on the bottom electrode; and the P-type thermoelectric leg is connected in series to the N-type thermoelectric leg by the top electrode. The thermoelectric array display has strong concealment of information transmission, can effectively reduce heat generation of a device, and can implement long-distance signal transmission.

### CROSS REFERENCE TO THE RELATED APPLICATIONS

This application is the national phase entry of International Application No. PCT/CN2022/132212, filed on Nov. 16, 2022, which is based upon and claims priority to Chinese Patent Applications No. 202111498529.7 and No. 202111517702.3, both filed on Dec. 9, 2021, the entire contents of which are incorporated herein by reference.

### TECHNICAL FIELD

The present invention belongs to the field of infrared detection technologies, and relates to a thermoelectric array display and a manufacturing method thereof, in particular to a thermoelectric array display based on infrared detector imaging and recognition and a manufacturing method thereof.

### BACKGROUND

A thermoelectric array display includes at least one or more pairs of thermoelectric devices, which are usually connected in series or in parallel to form a geometric pattern, a character, or a two-dimensional code shape. The devices have a certain temperature difference when powered on. Signals are collected using an infrared detector.

Various forms and designs of array displays or display screens currently on the market implement patterning and signal conversion by light-emitting diodes or color changing materials. These displays also have several problems:
firstly, these patterns are visible to the naked eyes and have limitations in application to military and more fields, for example, light-emitting devices have high heat and low concealment and are easily detected by others;
secondly, although liquid crystal display screens have low heat generation, they are difficult to observe at night and cannot be recognized;
thirdly, light-emitting materials can only produce a kind of pattern or character due to single color change, such that the single content limits its practicability in signal transmission and military field;
fourthly, the displays are expensive and complex in process; and
fifthly, heating devices used at present have single patterns, and the patterns cannot be changed after shaping.

### SUMMARY

To solve the above technical problems existing in the background, the present invention provides a thermoelectric array display which has strong concealment of information transmission, can effectively reduce heat generation of a device, and can implement long-distance signal transmission.

To achieve the above objective, the present invention adopts the following technical solution:

There is provided a thermoelectric array display, including at least a first pixel, where the first pixel includes a bottom electrode, a P-type thermoelectric leg, an N-type thermoelectric leg, and a top electrode; the P-type thermoelectric leg is arranged on the bottom electrode; and the P-type thermoelectric leg is connected in series to the N-type thermoelectric leg by the top electrode.

As a preference, according to the present invention, the thermoelectric array display further includes a second pixel connected in series to the first pixel, where a structure of the second pixel is identical to a structure of the first pixel.

As a preference, in the present invention, the N-type thermoelectric leg of the first pixel is connected in series to a P-type thermoelectric leg of the second pixel by a bottom electrode of the second pixel.

As a preference, in the present invention, a distance between the second pixel and the first pixel is 0.2 mm to 5 cm, more preferably 0.5 mm to 5 cm.

As a preference, in the present invention, a thermally conductive and insulating material is filled between the second pixel and the first pixel, the thermally conductive and insulating material being silica gel or polydimethylsiloxane (PDMS).

As a preference, in the present invention, the top electrode is a metallic material or a non-metallic material; when the top electrode is the metal material, the top electrode is gold, silver, or copper; and when the top electrode is the non-metallic material, the top electrode is carbon paste.

As a preference, in the present invention, both the P-type thermoelectric leg and the N-type thermoelectric leg are manufactured from bismuth telluride, antimony telluride, or a magnesium silicon material.

As a preference, in the present invention, the top electrode is connected to the top of the P-type thermoelectric leg and the top of the N-type thermoelectric leg by a solder or a conductive adhesive; and the conductive adhesive is silver paste, copper paste, or solder paste.

As a preference, in the present invention, the bottom electrode includes a bottom electrode substrate and a conductive layer coated on the bottom electrode substrate; the top electrode includes a top electrode substrate and a conductive layer coated on the top electrode substrate; both the bottom electrode substrate and the top electrode substrate are manufactured from paper, polyimide, polyethylene terephthalate (PET), polyvinyl chloride (PVC), silicon dioxide, aluminum silicate, an epoxy resin substrate plate, aluminum nitride, or aluminum oxide; and both the P-type thermoelectric leg and the N-type thermoelectric leg are circular, square, triangular, or polygonal.

A method for manufacturing the thermoelectric array display as described above, the method including the following steps:
1): manufacturing a bottom electrode:
1.1): determining a bottom electrode according to a required pattern or character, determining a size of the bottom electrode, and determining a spacing between a top electrode and the bottom electrode, where the spacing is not less than 0.5 mm, preferably not less than 0.2 mm;
1.2): drawing the top electrode and the bottom electrode using vector graphics software and then customizing a mesh plate with an appropriate number of meshes; and
1.3): fixing a bottom electrode substrate, coating the mesh plate with silver paste, coating the bottom electrode substrate with silver paste by using a scraper knife, taking away the mesh plate after scraping, and drying the silver paste, to obtain the bottom electrode;
2): manufacturing pixels:
2.1): preparing an adhesive, where the adhesive is obtained by adding methyl cellulose into a mixed solution of water and ethanol (a percentage by volume of the ethanol is not less than 95%) according to a volume ratio of the water to the ethanol of 1:(0.8-1), and stirring for dissolving at room temperature;
2.2): preparing P-type thermoelectric ink and N-type thermoelectric ink:
crushing a P-type thermoelectric bar and an N-type thermoelectric bar, then screening with a 100-mesh sieve, and mixing screened fine powder (taking a part under the sieve) with the adhesive to prepare the printable thermoelectric ink;
2.3): fixing the bottom electrode manufactured in step 1.3), and printing the thermoelectric ink prepared in step 2.2) onto the bottom electrode, where the printing is screen printing, three-dimensional (3D) printing, or ink-jet printing;
2.4): performing curing, sintering, and cold pressing on a product obtained in step 2.3) to form a P-type thermoelectric leg and an N-type thermoelectric leg, where a specific method for implementing the curing and sintering includes: firstly, performing cold pressing at room temperature, and then performing curing and sintering in nitrogen, argon, or vacuum at 300° C.;
2.5): connecting the top electrode at a top of the P-type thermoelectric leg and a top of the N-type thermoelectric leg by solder paste, to form a first pixel; and
2.6): repeating steps 2.1)-2.5), to form a plurality of pixels; and
3): according to design requirements, connecting the plurality of pixels in series, and filling a thermally conductive and insulating material between adjacent two of the pixels, to form the thermoelectric array display, where the thermoelectric array display is a pattern, a character, a number, a letter, a symbol, and/or a cartoon character.

Compared with the prior art, the present invention has the following advantages and beneficial effects:

The present invention provides a thermoelectric array display and a manufacturing method thereof. The thermoelectric array display includes at least a first pixel, where the first pixel includes a bottom electrode, a P-type thermoelectric leg, an N-type thermoelectric leg, and a top electrode; the P-type thermoelectric leg is arranged on the bottom electrode; and the P-type thermoelectric leg is connected in series to the N-type thermoelectric leg by the top electrode. According to the present invention, the electrodes are printed on the substrates and P/N-type thermoelectric materials are prepared; at least one pair of P/N-type thermoelectric devices serves as one pixel; after the pixel is energized, a temperature difference is generated; a plurality of characters can be switched by a logic circuit; a refrigeration or heating end can be adjusted by adjusting a direction of current in positive and negative electrodes, such that heating and refrigeration can be implemented; when the current flows into the N-type thermoelectric leg, the top of the pixel is the refrigeration end, and when the current flows into the bottom of the P-type thermoelectric leg, the top of the pixel is the heating end; different color distributions are displayed under infrared detection, so as to recognize patterns or characters; the pattern or character can be changed by controlling a current flow path in the circuit, thereby implementing signal output transformation; the pattern or character cannot be recognized by the naked eyes during operation; the devices can work well during the day and at night and respond quickly; in addition, different substrates can be used, and materials with protective colors can be selected as the substrates to be hidden in an environment, such that the display has strong concealment and is suitable for military applications. Moreover, due to the fact that the thermoelectric devices, namely, the pixels neatly arranged in transverse and longitudinal directions are disposed on the substrates in the present invention, a high integration level is achieved; the pixels can be adjusted in size as needed; the entire manufacturing process is simple; the display is low in cost, electrically stable, suitable for miniaturization, and convenient to carry and hide; and the amplification can also implement long-distance signal transmission. Furthermore, two ends of the thermoelectric array display provided by the present invention have low temperatures, such that the substrate will not be damaged; and the refrigeration end is outward, which can reduce the release of heat and lower the risk of being discovered when working in a concealed environment.

### BRIEF DESCRIPTION OF THE DRAWINGS

FIG. 1 is a schematic structural diagram of an embodiment of a thermoelectric array display provided by the present invention;

FIG. 2 is a top view of FIG. 1;

FIG. 3 is a 3D enlarged view of a pixel of a thermoelectric array display according to the present invention;

FIG. 4 is a schematic circuit diagram of a thermally conductive and insulating material of a top substrate and an electrode of a thermoelectric array display according to the present invention; and

FIG. 5 is a schematic diagram obtained by detection based on an infrared detector.

In the drawings:
1—bottom electrode; 2—thermoelectric leg; 3—P-type thermoelectric leg; 4—N-type thermoelectric leg; 5—top electrode; and 7—thermally conductive and insulating material.

### DETAILED DESCRIPTION OF THE EMBODIMENTS

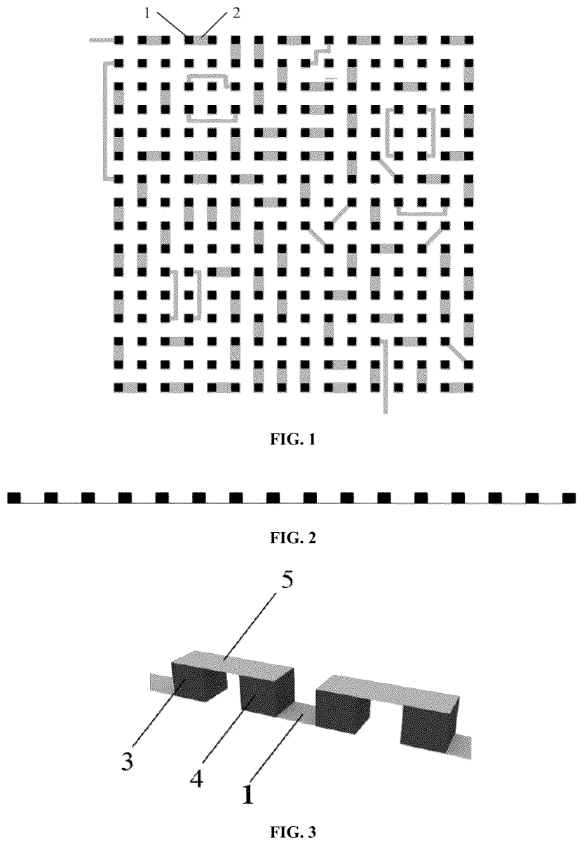

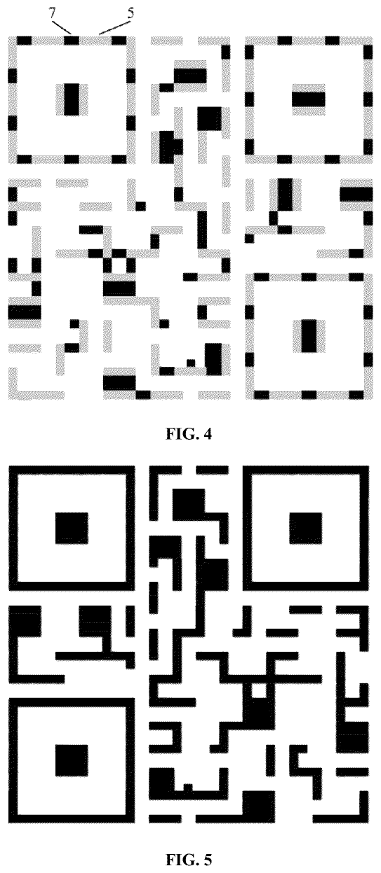

Referring to FIG. 1, FIG. 2, and FIG. 3, the present invention provides a thermoelectric array display, including at least a first pixel, where the first pixel includes a bottom electrode 1, a P-type thermoelectric leg 3, an N-type thermoelectric leg 4, and a top electrode 5; both the P-type thermoelectric leg 3 and the N-type thermoelectric leg 4 are arranged on the bottom electrode 1; a bottom of the P-type thermoelectric leg 3 is not connected to a bottom of the N-type thermoelectric leg 4; and a top of the P-type thermoelectric leg 3 is connected in series to a top of the N-type thermoelectric leg 4 by the top electrode 5. The P-type thermoelectric leg 3 can be directly formed on the bottom electrode 1 by means of printing, or the P-type thermoelectric leg 3 and the N-type thermoelectric leg 4 can be arranged on the bottom electrode 1 by welding cut thermoelectric particles or by a conductive adhesive for connection.

The thermoelectric array display further includes a second pixel connected in series to the first pixel, where a structure of the second pixel is identical to a structure of the first pixel.

The N-type thermoelectric leg 4 of the first pixel is connected in series to a P-type thermoelectric leg 3 of the second pixel by a bottom electrode 1 of the second pixel, and a distance between the second pixel and the first pixel is 0.2 mm to 5 cm. A thermally conductive and insulating material 7 is filled between the second pixel and the first pixel, the thermally conductive and insulating material 7 being silica gel.

The top electrode 5 is a metallic material or a non-metallic material; when the top electrode 5 is the metal material, the top electrode 5 is gold paste, silver paste, or copper paste; and when the top electrode 5 is the non-metallic material, the top electrode 5 is carbon paste.

Both the P-type thermoelectric leg 3 and the N-type thermoelectric leg 4 are manufactured from bismuth telluride, antimony telluride, a magnesium silicon material (Mg₃Si₂), or silver selenide.

The top electrode 5 is connected to the top of the P-type thermoelectric leg 3 and the top of the N-type thermoelectric leg 4 by a solder or a conductive adhesive; and the conductive adhesive is silver paste, copper paste, or solder paste.

The bottom electrode 1 includes a bottom electrode substrate and a conductive layer coated on the bottom electrode substrate; the top electrode 5 includes a top electrode substrate and a conductive layer coated on the top electrode substrate; both the bottom electrode substrate and the top electrode substrate are manufactured from paper, polyimide, polyethylene terephthalate (PET), polyvinyl chloride (PVC), silicon dioxide, aluminum silicate, or aluminum oxide; and both the P-type thermoelectric leg 3 and the N-type thermoelectric leg 4 are circular, square, triangular, or polygonal.

There is provided a method for manufacturing the thermoelectric array display as recited above, the method including the following steps:
1): manufacturing a bottom electrode, where as shown in FIG. 1, the bottom electrode is manufactured by printing silver paste onto a flexible substrate through screen printing; a conductive material on the flexible substrate is not limited to the silver paste and may be copper paste or the like, and a thermoelectric material may be bismuth telluride, antimony telluride, or other P/N-type thermoelectric materials; the thermoelectric material may be printed through a designed screen printing plate, or cut thermoelectric particles may be connected to an electrode by means of welding; a top electrode is connected through silver paste or solder paste which can be used to reduce a contact resistance; and exemplarily, the manufacturing of the bottom electrode can specifically include the following steps:
1.1): determining a bottom electrode according to a required pattern or character, determining a size of the bottom electrode, and determining a spacing between the top electrode and the bottom electrode, where the spacing is not less than 0.2 mm, preferably not greater than 5 cm; and every two adjacent thermoelectric legs have an interval of 0.2 mm to 1 cm;
1.2): drawing the top electrode and the bottom electrode using vector graphics software and then customizing a mesh plate with an appropriate number of meshes; and
1.3): fixing a bottom electrode substrate, coating the mesh plate with silver paste, coating the bottom electrode substrate with silver paste by using a scraper knife, taking away the mesh plate after scraping, and drying the silver paste, to obtain the bottom electrode;
2): manufacturing pixels:
2.1): preparing an adhesive, where the adhesive is obtained by adding methyl cellulose into a mixed solution of water and ethanol (absolute ethanol) according to a solid-liquid mass ratio of 0.02:1 and a volume ratio of the water to the ethanol of 1:1, and stirring for dissolving at 120 rpm and room temperature;
2.2): preparing P-type thermoelectric ink and N-type thermoelectric ink:
crushing a P-type thermoelectric bar and an N-type thermoelectric bar, then screening with a 100-mesh sieve, mixing screened fine powder (taking a part under the sieve) with the adhesive (according to a solid-liquid ratio of 4.5 g:1 mL), and stirring at 110 rpm and room temperature to prepare the printable thermoelectric ink;
2.3): fixing the bottom electrode manufactured in step 1.3), and printing the thermoelectric ink prepared in step 2.2) onto the bottom electrode, where the printing is screen printing, three-dimensional (3D) printing, or ink-jet printing;
2.4): performing curing, sintering, and cold pressing on a product obtained in step 2.3) to form a P-type thermoelectric leg 3 and an N-type thermoelectric leg 4, where a specific method for implementing the curing and sintering includes: firstly, performing cold pressing at room temperature, and then performing curing and sintering in nitrogen, argon, or vacuum at 300° C.;
2.5): connecting the top electrode 5 at a top of the P-type thermoelectric leg 3 and a top of the N-type thermoelectric leg 4 by solder paste, to form a first pixel; and
2.6): repeating steps 2.1)-2.5), to form a plurality of pixels; and
3): according to design requirements, connecting the plurality of pixels in series, and filling a thermally conductive and insulating material 7 between adjacent two of the pixels, to form the thermoelectric array display, where the thermoelectric array display is a pattern, a character, a number, a letter, a symbol, and/or a cartoon character.

It should be noted that exemplarily, the thermoelectric array display according to the present invention is described in detail by using a two-dimensional code pattern as an example, where the two-dimensional code pattern is only used to explain one of embodiments, and if other specific characters or patterns are needed, connecting electrodes are also changed accordingly; moreover, to pattern required pixels, it is required to connect patterns in series or connect two or more circuits to a same current, so as to display a same color depth under an infrared detector; furthermore, each pixel cannot be too small, otherwise the infrared detector may not observe it clearly, and if each pixel is too large, too many areas are taken up, which is not conducive to the miniaturization; in addition, every two adjacent pixels cannot be too close, otherwise the pixel at a heating or refrigeration end will affect the pixel that does not generate a signal, resulting in fuzzy patterns or signal display errors.

The thermoelectric array display can be arranged according to the appearance and shape and the process and artistic design, and may be circular, triangular, square, polygonal, or fan-shaped; the substrate color used may also be configured to be any color according to requirements; and the substrate may be a transparent or opaque insulating material.

FIG. 4 is a top-insulating and high-thermal-conductivity pattern. To transfer heat between two adjacent pixels to a gap between the pixels, the thermally conductive and insulating material 7 plays a role in flow guide on the top and acts as a medium to transfer heat or cold to a place where it is needed, because only the P/N-type thermoelectric leg can generate heat and perform refrigeration, and the thermally conductive and insulating material 7 itself does not generate heat and perform refrigeration; for example, to enable the gap between the two thermoelectric legs or pixels to receive the heat or cold, and to avoid the two thermoelectric legs or pixels being in communication for electric conduction, the thermally conductive and insulating material 7 is printed by means of screen printing to guide the heat into the gap that needs to be connected; moreover, an insulating layer and the top electrode are located on a same surface, the color uniformity of the back surface of a device is ensured, and the heat is better transferred; and the top electrode is connected to the thermoelectric leg by the solder paste, the solder paste is printed on the top electrode, then the bottom device is fixed, the top electrode and the bottom device are positioned by a fixture, and heat welding is performed in a certain vacuum or protective atmosphere. In addition, when the thermoelectric array display works, a certain current needs to be connected to generate a temperature difference, and then it can be seen through observation of the infrared detector that the pixel connected to the current has different color from the pixel not connected to the current or with different current, and the pixels with the same current have a same color, thereby implementing imaging. A working principle of the P/N-type thermoelectric leg is based on the Peltier effect, that is, when a circuit composed of two different P/N-type conductors is connected to a direct current, other heat will be released at a joint in addition to Joule heat, while the other end absorbs heat for refrigeration, and such a phenomenon is reversible; and when a direction of current is changed, heat release and absorption ends will change accordingly. When the direct current is connected, the current flows into the bottom end of the N-type thermoelectric leg, such that heat is absorbed on the top for refrigeration; and when the current flows into the bottom of the P-type thermoelectric leg, the top of the pixel is the heat release end. When the thermoelectric array display is powered on to work, its temperature will differ from a temperature of a surrounding environment, and based on a working principle of the infrared detector, different temperatures can be distinguished and the temperature difference can be displayed in different colors, such that an image built by the temperatures can be obtained. For example, FIG. 5 is a two-dimensional code pattern observed under the infrared detector after being powered on in this embodiment.

What is claimed is:

1. A thermoelectric array display, comprising a first pixel, wherein the first pixel comprises a bottom electrode, a P-type thermoelectric leg, an N-type thermoelectric leg, and a top electrode; the P-type thermoelectric leg is arranged on the bottom electrode; and a top of the P-type thermoelectric leg is connected in series to a top of the N-type thermoelectric leg by the top electrode.

2. The thermoelectric array display according to claim 1, further comprising a second pixel connected in series to the first pixel, wherein a structure of the second pixel is identical to a structure of the first pixel.

3. The thermoelectric array display according to claim 2, wherein the N-type thermoelectric leg of the first pixel is connected in series to a P-type thermoelectric leg of the second pixel by a bottom electrode of the second pixel.

4. The thermoelectric array display according to claim 3, wherein a distance between the second pixel and the first pixel is 0.2 mm to 5 cm.

5. The thermoelectric array display according to claim 2, wherein a thermally conductive and insulating material is filled between the second pixel and the first pixel, wherein the thermally conductive and insulating material is silica gel or polydimethylsiloxane (PDMS).

6. The thermoelectric array display according to claim 5, wherein the top electrode is a metallic material or a non-metallic material; when the top electrode is the metal material, the top electrode is gold, silver, or copper; and when the top electrode is the non-metallic material, the top electrode is carbon paste.

7. The thermoelectric array display according to claim 6, wherein both the P-type thermoelectric leg and the N-type thermoelectric leg are manufactured from bismuth telluride, antimony telluride, a magnesium silicon material, or silver selenide.

8. The thermoelectric array display according to claim 7, wherein the top electrode is connected to the top of the P-type thermoelectric leg and the top of the N-type thermoelectric leg by a solder or a conductive adhesive; and the conductive adhesive is silver paste, copper paste, or solder paste.

9. The thermoelectric array display according to claim 8, wherein the bottom electrode comprises a bottom electrode substrate and a first conductive layer coated on the bottom electrode substrate; the top electrode comprises a top electrode substrate and a second conductive layer coated on the top electrode substrate; both the bottom electrode substrate and the top electrode substrate are manufactured from paper, polyimide, polyethylene terephthalate (PET), polyvinyl chloride (PVC), silicon dioxide, aluminum silicate, an epoxy resin substrate plate, aluminum nitride, or aluminum oxide; and both the P-type thermoelectric leg and the N-type thermoelectric leg are circular, square, triangular, or polygonal.

10. A method for manufacturing the thermoelectric array display according to claim 9, comprising the following steps:
1): manufacturing the bottom electrode:
1.1): determining the bottom electrode according to a required pattern or character, determining a size of the bottom electrode, and determining a spacing between the top electrode and the bottom electrode, wherein the spacing is greater than or equal to 0.2 mm;
1.2): drawing the top electrode and the bottom electrode using vector graphics software and then customizing a mesh plate with an appropriate number of meshes; and
1.3): fixing the bottom electrode substrate, coating the mesh plate with silver paste, coating the bottom electrode substrate with silver paste by using a scraper knife, taking away the mesh plate after scraping, and drying the silver paste, to obtain the bottom electrode;
2): manufacturing pixels:
2.1): preparing an adhesive, wherein the adhesive is obtained by adding methyl cellulose into a mixed solution of water and ethanol according to a mass ratio of the methyl cellulose to the mixed solution of 0.02:1 and a volume ratio of the ethanol to the water of (0.8-1):1, and stirring for dissolving at room temperature;
2.2): preparing P-type thermoelectric ink and N-type thermoelectric ink: crushing a P-type thermoelectric bar and an N-type thermoelectric bar separately, then screening with a 100-mesh sieve, mixing screened P-type fine powder and N-type fine powder with the adhesive prepared in step 2.1) according to a solid-liquid ratio of 4.5 g:1 mL, and stirring at room temperature to prepare the P-type thermoelectric ink and the N-type thermoelectric ink;
2.3): fixing the bottom electrode manufactured in step 1.3), and forming the P-type thermoelectric ink and the N-type thermoelectric ink prepared in step 2.2) on the bottom electrode by printing, wherein the printing is screen printing, three-dimensional (3D) printing, or ink-jet printing;
2.4): performing curing, sintering, and cold pressing on a product obtained in step 2.3) to form the P-type thermoelectric leg and the N-type thermoelectric leg, wherein a specific method for implementing the curing and sintering comprises: firstly, performing cold pressing at room temperature, and then performing curing and sintering in nitrogen, argon, or vacuum at 300° C.;
2.5): connecting the top electrode) at the top of the P-type thermoelectric leg and the top of the N-type thermoelectric leg by the solder paste to form the first pixel; and
2.6): repeating steps 2.1)-2.5), to form a plurality of pixels; and
3): according to design requirements, connecting the plurality of pixels in series, and filling the thermally conductive and insulating material between adjacent two pixels of the plurality of pixels to form the thermoelectric array display, wherein the thermoelectric array display is a pattern, a character, a number, a letter, a symbol, and/or a cartoon character.

11. The thermoelectric array display according to claim 3, wherein a thermally conductive and insulating material is filled between the second pixel and the first pixel, wherein the thermally conductive and insulating material is silica gel or polydimethylsiloxane (PDMS).

12. The thermoelectric array display according to claim 11, wherein the top electrode is a metallic material or a non-metallic material; when the top electrode is the metal material, the top electrode is gold, silver, or copper; and when the top electrode is the non-metallic material, the top electrode is carbon paste.

13. The thermoelectric array display according to claim 12, wherein both the P-type thermoelectric leg and the N-type thermoelectric leg are manufactured from bismuth telluride, antimony telluride, a magnesium silicon material, or silver selenide.

14. The thermoelectric array display according to claim 13, wherein the top electrode is connected to the top of the P-type thermoelectric leg and the top of the N-type thermoelectric leg by a solder or a conductive adhesive; and the conductive adhesive is silver paste, copper paste, or solder paste.

15. The thermoelectric array display according to claim 14, wherein the bottom electrode comprises a bottom electrode substrate and a first conductive layer coated on the bottom electrode substrate; the top electrode comprises a top electrode substrate and a second conductive layer coated on the top electrode substrate; both the bottom electrode substrate and the top electrode substrate are manufactured from paper, polyimide, polyethylene terephthalate (PET), polyvinyl chloride (PVC), silicon dioxide, aluminum silicate, an epoxy resin substrate plate, aluminum nitride, or aluminum oxide; and both the P-type thermoelectric leg and the N-type thermoelectric leg are circular, square, triangular, or polygonal.

16. The thermoelectric array display according to claim 4, wherein a thermally conductive and insulating material is filled between the second pixel and the first pixel, wherein the thermally conductive and insulating material is silica gel or polydimethylsiloxane (PDMS).

17. The thermoelectric array display according to claim 16, wherein the top electrode is a metallic material or a non-metallic material; when the top electrode is the metal material, the top electrode is gold, silver, or copper; and when the top electrode is the non-metallic material, the top electrode is carbon paste.

18. The thermoelectric array display according to claim 17, wherein both the P-type thermoelectric leg and the N-type thermoelectric leg are manufactured from bismuth telluride, antimony telluride, a magnesium silicon material, or silver selenide.

19. The thermoelectric array display according to claim 18, wherein the top electrode is connected to the top of the P-type thermoelectric leg and the top of the N-type thermoelectric leg by a solder or a conductive adhesive; and the conductive adhesive is silver paste, copper paste, or solder paste.

20. The thermoelectric array display according to claim 19, wherein the bottom electrode comprises a bottom electrode substrate and a first conductive layer coated on the bottom electrode substrate; the top electrode comprises a top electrode substrate and a second conductive layer coated on the top electrode substrate; both the bottom electrode substrate and the top electrode substrate are manufactured from paper, polyimide, polyethylene terephthalate (PET), polyvinyl chloride (PVC), silicon dioxide, aluminum silicate, an epoxy resin substrate plate, aluminum nitride, or aluminum oxide; and both the P-type thermoelectric leg and the N-type thermoelectric leg are circular, square, triangular, or polygonal.
